(19) United States
(12) Patent Application Publication
(10) Pub. No.: US 2020/0313010 A1
(43) Pub. Date: Oct. 1, 2020

(54) SOLAR CELL AND SOLAR CELL MODULE

(71) Applicant: PANASONIC CORPORATION, Osaka (JP)

(72) Inventor: Shin NANBA, Osaka (JP)

(21) Appl. No.: 16/831,407

(22) Filed: Mar. 26, 2020

(30) Foreign Application Priority Data
Mar. 28, 2019 (JP) 2019-065137

(51) Int. Cl. H01L 31/0352; H01L 31/0216; H01L 31/0224; H01L 31/0236; H01L 31/05; H01L 31/0747; H01L 31/20

(52) U.S. Cl. CPC H01L 31/03529; H01L 31/02167; H01L 31/022425; H01L 31/202; H01L 31/0504; H01L 31/0747; H01L 31/02363

(57) ABSTRACT

A solar cell includes a semiconductor substrate having a first principal surface and a second principal surface and having a first conductivity type, a third amorphous silicon layer disposed on the second principal surface, and a fourth amorphous silicon layer disposed on the third amorphous silicon layer and having a second conductivity type different from the first conductivity type. The impurity concentration of the first conductivity type in the third amorphous silicon layer is higher than the impurity concentration of the first conductivity type in the semiconductor substrate and lower than the impurity concentration of the second conductivity type in the fourth amorphous silicon layer.

### CROSS REFERENCE TO RELATED APPLICATION

This application claims the benefit of priority of Japanese Patent Application Number 2019-065137, filed on Mar. 28, 2019, the entire content of which is hereby incorporated by reference.

### TECHNICAL FIELD

The present disclosure relates to a solar cell and a solar cell module.

### BACKGROUND ART

Solar cells convert clean, inexhaustibly supplied sunlight directly into electricity and are thus expected to serve as a new energy source. For example, see International Patent Publication No. 2016/194301.

### SUMMARY

There is a desire for a solar cell with even more improved power generation performance. Some aspects of the present invention are directed to providing a solar cell and a solar cell module with improved power generation performance.

To this end, a solar cell according to one aspect of the present invention includes a semiconductor substrate, a first silicon layer, and a second silicon layer. The semiconductor substrate has a first conductivity type. The first silicon layer is disposed on a principal surface of the semiconductor substrate. The first silicon layer includes an amorphous silicon-based thin film. The second silicon layer is disposed on the first silicon layer. The second silicon layer includes a silicon-based thin film having a second conductivity type different from the first conductivity type. An impurity concentration of the first conductivity type in the first silicon layer is higher than the impurity concentration of the first conductivity type in the semiconductor substrate and lower than the impurity concentration of the second conductivity type in the second silicon layer.

A solar cell module according to one aspect of the present invention includes a solar cell string electrically connecting a plurality of solar cells in series with a plurality of wire members. The plurality of solar cells are each the solar cell according to the aspect of the present invention described above.

Some aspects of the present invention can provide a solar cell and a solar cell module with improved power generation performance.

### BRIEF DESCRIPTION OF THE DRAWINGS

The figures depict one or more implementations in accordance with the present teaching, by way of examples only, not by way of limitations. In the figures, like reference numerals refer to the same or similar elements.

FIG. 1 is a sectional view illustrating a structure of a solar cell according to Embodiment 1.

FIG. 2 is a plan view of a light-receiving surface side illustrating a structure of the solar cell according to Embodiment 1.

FIG. 3 illustrates an impurity concentration profile according to Embodiment 1.

FIG. 4 is a front view in which an amorphous silicon layer is formed in substantially the entire region on a semiconductor substrate.

FIG. 5 is a sectional view illustrating a structure of a solar cell according to Embodiment 2.

FIG. 6 is a sectional view illustrating a structure of a solar cell module according to Embodiment 3.

FIG. 7 is a plan view of a light-receiving surface side illustrating a structure of the solar cell module according to Embodiment 3.

### DETAILED DESCRIPTION

Hereinafter, embodiments of the present invention will be described in detail with reference to the drawings. The embodiments described below illustrate some specific examples of the present invention. Thus, the numerical values, the shapes, the materials, the constituent elements, the arrangement of the constituent elements, the connection modes, the steps, the orders of the steps, and so on illustrated in the following embodiments are examples and are not intended to limit the present invention. Among the constituent elements described in the following embodiments, any constituent element that is not described in an independent claim expressing the broadest concept of the present invention is to be construed as an optional constituent element.

The drawings are schematic diagrams and do not necessarily provide the exact depiction. In the drawings, substantially identical configurations are given identical reference characters. Furthermore, duplicate descriptions may be omitted or simplified.

In the present specification, a “light-receiving surface” of a solar cell refers to a surface that allows a larger amount of light to enter the solar cell therethrough than does a “back surface” opposite to the front surface of the solar cell. There is also a case where no light enters the solar cell through its back surface. A “light-receiving surface” of a semiconductor substrate refers to a surface facing a light-receiving surface of a solar cell. A “back surface” of a semiconductor substrate refers to a surface opposite to a light-receiving surface of a solar cell module. A “light-receiving surface” of a solar cell module refers to a surface that faces a light-receiving surface of a solar cell and that allows light to enter the solar cell module therethrough. A “back surface” of a solar cell module refers to a surface opposite to the light-receiving surface of the solar cell module. The expression “a second member is provided on a first member” or the like is not limited to a case where the first and second members are so provided as to be in direct contact with each other, unless specific limitation is indicated. In other words, the above expression includes a case where another member is present between the first and second members.

With regard to the expression “substantially . . . ”, in one example, the expression “substantially identical” encompasses a case of being essentially identical as well as a case of being exactly identical.

### Embodiment 1

### [1.1 Configuration of Solar Cell According to Embodiment 1]

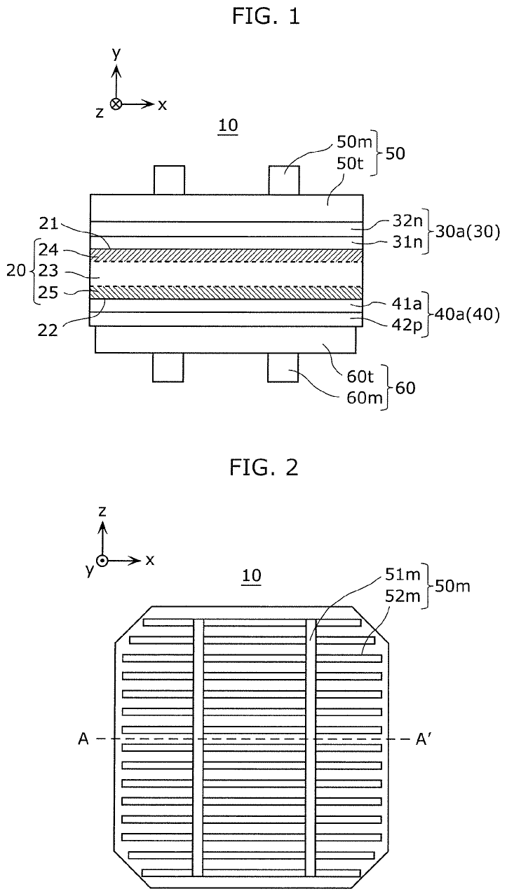

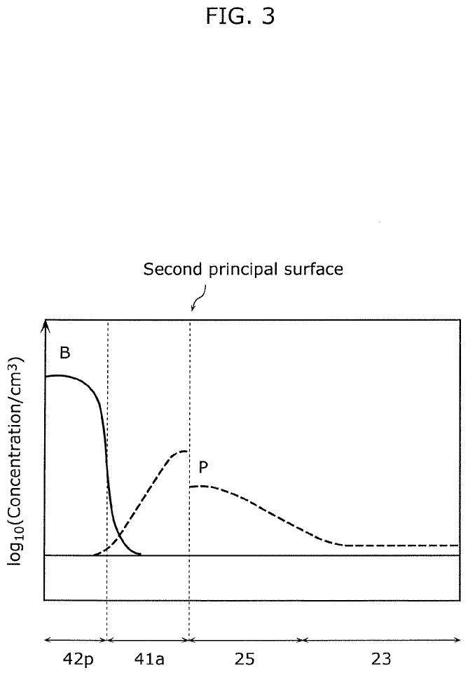

A schematic configuration of solar cell 10 according to Embodiment 1 will be described with reference to FIGS. 1 to 3. FIG. 1 is a sectional view illustrating a structure of solar cell 10 according to Embodiment 1. FIG. 2 is a plan view of a light-receiving surface side illustrating a structure of solar cell 10 according to Embodiment 1. FIG. 1 is a sectional view of solar cell 10 taken along the A-A′ line indicated in FIG. 2. FIG. 3 illustrates an impurity concentration profile according to Embodiment 1.

As illustrated in FIG. 1, solar cell 10 includes semiconductor substrate 20 of a first conductivity type, first semiconductor layer 30 of the first conductivity type, second semiconductor layer 40 of a second conductivity type, first electrode 50, and second electrode 60. The second conductivity type is a conductivity type different from the first conductivity type.

Semiconductor substrate 20 has the first conductivity type that is n-type or p-type. Semiconductor substrate 20 has first principal surface 21 and second principal surface 22 that are opposite to each other. First principal surface 21 is a surface facing a light-receiving surface or a back surface of solar cell 10. Second principal surface 22 is a surface opposite to the first principal surface.

Semiconductor substrate 20 can generate carriers upon receiving light. A carrier refers to an electron and a hole generated as light is absorbed by semiconductor substrate 20.

For semiconductor substrate 20, a crystalline silicon substrate, such as a monocrystalline silicon substrate or a polycrystalline silicon substrate, can be used, for example. A substrate other than a crystalline silicon substrate can also be used for semiconductor substrate 20. For example, a typical semiconductor substrate, such as a germanium (Ge) semiconductor substrate, a IV-IV compound semiconductor substrate represented by silicon carbide (SiC) and silicon germanium (SiGe), or a III-V compound semiconductor substrate represented by gallium arsenide (GaAs), gallium nitride (GaN), and indium phosphide (InP), can be used.

In the example described in the present embodiment, first principal surface 21 is a surface facing the light-receiving surface of solar cell 10, and second principal surface 22 is a surface facing the back surface of solar cell 10.

In order to increase the utilization efficiency of entering light, semiconductor substrate 20 may have a textured structure with a plurality of concavities and convexities in first principal surface 21, which is the surface facing the light-receiving surface of solar cell 10. Meanwhile, second principal surface 22 of semiconductor substrate 20 may have a textured structure with a plurality of concavities and convexities or may be a planar surface without the textured structure. The height of the textured structure is, for example, no less than 1 μm nor more than 20 μm or preferably no less than 2 μm nor more than 8 μm.

In the example described in the present embodiment, a monocrystalline silicon substrate is used for semiconductor substrate 20, the first conductivity type is n-type, and the second conductivity type different from the first conductivity type is p-type.

The thickness of semiconductor substrate 20 is, for example, no less than 10 μm nor more than 400 μm or preferably no less than 50 μm nor more than 150 μm. A dopant, such as phosphorus (P), arsenic (As), or antimony (Sb), is added to semiconductor substrate 20 as an impurity of the first conductivity type, for example.

The textured structure in semiconductor substrate 20 is, for example, a concave and convex structure in which quadrangular pyramids having inclined faces in a plane corresponding to a specific plane orientation of semiconductor substrate 20 are arrayed two-dimensionally. Providing the textured structure in first principal surface 21 and second principal surface 22 of semiconductor substrate 20 makes it possible to reflect and/or diffract light entering solar cell 10 in a complex manner and to increase the utilization efficiency of the entering light.

Solar cell 10 includes first semiconductor layer 30 of the first conductivity type, which is the same as the conductivity type of semiconductor substrate 20, provided on first principal surface 21 of semiconductor substrate 20. In addition, solar cell 10 includes second semiconductor layer 40 of the second conductivity type, which is different from the conductivity type of semiconductor substrate 20, provided on second principal surface 22 of semiconductor substrate 20.

With the surface field effect, first semiconductor layer 30 can suppress carrier recombination in first principal surface 21 of semiconductor substrate 20 and in the vicinity thereof. Second semiconductor layer 40 forms a p-n junction with semiconductor substrate 20 and can generate electromotive force through carrier separation.

Semiconductor substrate 20 includes first impurity region 23 of the first conductivity type. The impurity concentration of the first conductivity type in first impurity region 23 is, for example, no less than 5×10¹³ cm⁻³ nor more than 1×10¹⁷ cm⁻³ or preferably no less than 5×10¹⁴ cm⁻³ nor more than 2×10¹⁶ cm⁻³.

Semiconductor substrate 20 also includes second impurity region 24 of the first conductivity type provided between first impurity region 23 and first semiconductor layer 30. The thickness of second impurity region 24 is, for example, no less than 5 nm nor more than 1 μm, preferably no less than 10 nm nor more than 500 nm, or more preferably no less than 20 nm nor more than 200 nm. The impurity concentration of the first conductivity type in second impurity region 24 is higher than the impurity concentration of the first conductivity type in first impurity region 23. The mean of the impurity concentration of the first conductivity type in second impurity region 24 is, for example, no less than 1×10¹⁷ cm⁻³ nor more than 1×10²⁰ cm⁻³ or preferably no less than 5×10¹⁷ cm⁻³ nor more than 1×10¹⁹ cm⁻³. Here, the thickness of second impurity region 24 is the distance, in the thickness direction of semiconductor substrate 20, from first principal surface 21 of semiconductor substrate 20 to a point where the impurity concentration of the first conductivity type in second impurity region 24 is reduced to one-tenth of a maximum value of the impurity concentration of the first conductivity type in second impurity region 24.

Semiconductor substrate 20 also includes third impurity region 25 of the first conductivity type provided between first impurity region 23 and second semiconductor layer 40. The thickness of third impurity region 25 is, for example, no less than 5 nm nor more than 1 μm, preferably no less than 10 nm nor more than 500 nm, or more preferably no less than 20 nm nor more than 200 nm. The impurity concentration of the first conductivity type in third impurity region 25 is higher than the impurity concentration of the first conductivity type in first impurity region 23. The mean of the impurity concentration of the first conductivity type in third impurity region 25 may be lower than the mean of the impurity concentration of the first conductivity type in second impurity region 24. The mean of the impurity concentration of the first conductivity type in third impurity region 25 is, for example, no less than 1×10¹⁷ cm⁻³ nor more than 1×10²⁰ cm⁻³ or preferably no less than 5×10¹⁷ cm⁻³ nor more than 1×10¹⁹ cm⁻³. Here, the thickness of third impurity region 25 is the distance, in the thickness direction of semiconductor substrate 20, from second principal surface 22 of semiconductor substrate 20 to a point where the impurity concentration of the first conductivity type in third impurity region 25 is reduced to one-tenth of a maximum value of the impurity concentration of the first conductivity type in third impurity region 25.

Providing first semiconductor layer 30 of the first conductivity type on first principal surface 21 of semiconductor substrate 20 of the first conductivity type makes it possible to suppress carrier recombination in the junction interface between semiconductor substrate 20 and first semiconductor layer 30 and in the vicinity thereof through the surface field effect. However, this technique cannot suppress the carrier recombination completely, and further measures for suppressing the carrier recombination are desired. Providing second impurity region 24 in first principal surface 21 of semiconductor substrate 20 allows the surface field effect to be enhanced, and the carrier recombination at the junction interface between semiconductor substrate 20 and first semiconductor layer 30 and in the vicinity thereof is further suppressed. This makes it possible to improve the power generation performance.

Meanwhile, with regard to second principal surface 22 of semiconductor substrate 20, an issue may arise in that boron (B) or the like, which is an impurity of the second conductivity type, is mixed in in the manufacturing process or the like and this leads to reduced conductive property in the vicinity of second principal surface 22 of semiconductor substrate 20. In other words, boron (B) or the like, which is an impurity of the second conductivity type, is mixed in to phosphorus (P) or the like, which is an impurity of the first conductivity type, having been added to semiconductor substrate 20 originally. This may notably increase the resistive property in the vicinity of second principal surface 22 of semiconductor substrate 20 and reduce the power generation performance. The impurity that could be mixed in in the manufacturing process and that could cause a decrease in the power generation performance as described above is not limited to boron (B), which is an impurity of the second conductivity type, and includes presumably hydrogen, oxygen, nitrogen, and fluorine. Providing third impurity region 25 in second principal surface 22 of semiconductor substrate 20 makes it possible to suppress the decrease in the conductive property that could arise in the vicinity of second principal surface 22 of semiconductor substrate 20 and to improve the power generation performance.

In the present embodiment, as illustrated in FIG. 1, first semiconductor layer 30 of the first conductivity type, which is the same as the conductivity type of semiconductor substrate 20, is provided in the entire region or in substantially the entire region on first principal surface 21 of semiconductor substrate 20. Substantially the entire region on first principal surface 21 of semiconductor substrate 20 is a region covering 90% or more of first principal surface 21 of semiconductor substrate 20. First semiconductor layer 30 has a function of suppressing recombination of carriers at the junction interface with semiconductor substrate 20 or in the vicinity thereof.

In the present embodiment, amorphous silicon layer 30a having the first conductivity type is used as first semiconductor layer 30 having the first conductivity type. Amorphous silicon layer 30a has a layered structure in which first amorphous silicon layer 31n of the first conductivity type and second amorphous silicon layer 32n of the first conductivity type are laminated in this order on first principal surface 21 of semiconductor substrate 20. First amorphous silicon layer 31n is provided on first principal surface 21 of semiconductor substrate 20. Second amorphous silicon layer 32n is provided on first amorphous silicon layer 31n. The mean of the impurity concentration of the first conductivity type in second amorphous silicon layer 32n is higher than the mean of the impurity concentration of the first conductivity type in first amorphous silicon layer 31n. In the present embodiment, the junction between semiconductor substrate 20 and first semiconductor layer 30 is a heterojunction.

First amorphous silicon layer 31n and second amorphous silicon layer 32n each contain an impurity of the first conductivity type, which is the same as the conductivity type of semiconductor substrate 20. In the present embodiment, a dopant, such as a phosphorus (P), arsenic (As), or antimony (Sb), is added to first amorphous silicon layer 31n and second amorphous silicon layer 32n as an impurity of the first conductivity type, for example. The impurity concentration of the first conductivity type in first amorphous silicon layer 31n and second amorphous silicon layer 32n is, for example, no less than 5×10¹⁹ cm⁻³ or preferably no less than 5×10²⁰ cm⁻³ nor more than 5×10²¹ cm⁻³.

First semiconductor layer 30 may be thick enough to sufficiently suppress recombination of carriers in first principal surface 21 of semiconductor substrate 20 and also thin enough to suppress absorption of entering light by first semiconductor layer 30 as much as possible. The thickness of first semiconductor layer 30 is no less than 2 nm nor more than 75 nm, for example. More specifically, the thickness of first amorphous silicon layer 31n is, for example, no less than 1 nm nor more than 25 nm or preferably no less than 2 nm nor more than 5 nm. The thickness of second amorphous silicon layer 32n is, for example, no less than 1 nm nor more than 50 nm or preferably no less than 2 nm nor more than 10 nm.

In the present embodiment, as illustrated in FIG. 1, second semiconductor layer 40 of the second conductivity type, which is different from the conductivity type of semiconductor substrate 20, is provided in the entire region or in substantially the entire region on second principal surface 22 of semiconductor substrate 20. Substantially the entire region on second principal surface 22 of semiconductor substrate 20 is a region covering 90% or more of second principal surface 22 of semiconductor substrate 20. Second semiconductor layer 40 has a function of suppressing recombination of carriers at the junction interface with semiconductor substrate 20 and a function of separating carriers by forming a p-n junction with the semiconductor substrate.

In the present embodiment, amorphous silicon layer 40a is used for second semiconductor layer 40. Amorphous silicon layer 40a has a layered structure in which third amorphous silicon layer 41a and fourth amorphous silicon layer 42p of the second conductivity type are laminated in this order on second principal surface 22 of semiconductor substrate 20. Third amorphous silicon layer 41a is provided on second principal surface 22 of semiconductor substrate 20. Fourth amorphous silicon layer 42p is provided on third amorphous silicon layer 41a. In the present embodiment, the junction between semiconductor substrate 20 and second semiconductor layer 40 is a heterojunction.

Third amorphous silicon layer 41a contains an impurity of the first conductivity type. A dopant, such as phosphorus (P), arsenic (As), or antimony (Sb), is added to third amorphous silicon layer 41a as an impurity of the first conductivity type, for example. The impurity concentration of the first conductivity type in third amorphous silicon layer 41a is, for example, no less than 1×10¹⁷ cm⁻³ or preferably no less than 1×10¹⁸ cm⁻³ nor more than 1×10²¹ cm⁻³. The impurity concentration of the first conductivity type in third amorphous silicon layer 41a is higher than the impurity concentration of the first conductivity type in first impurity region 23 and third impurity region 25 of semiconductor substrate 20. The impurity concentration of the first conductivity type in third amorphous silicon layer 41a may be lower than the impurity concentration of the first conductivity type in first amorphous silicon layer 31n and second amorphous silicon layer 32n. Third amorphous silicon layer 41a is an example of a first silicon layer formed by an amorphous silicon-based thin film. “Amorphous silicon-based” may include not only an amorphous silicon substance but also a crystallite substance and an oxygen or carbon impurity.

Fourth amorphous silicon layer 42p contains an impurity of the second conductivity type different from that of semiconductor substrate 20. A dopant, such as boron (B), is added to fourth amorphous silicon layer 42p as an impurity of the second conductivity type, for example. The impurity concentration of the second conductivity type in fourth amorphous silicon layer 42p is, for example, no less than 1×10¹⁹ cm⁻³ or preferably no less than 5×10²⁰ cm⁻³ nor more than 5×10²¹ cm⁻³. The impurity concentration of the second conductivity type in fourth amorphous silicon layer 42p is higher than the impurity concentration of the first conductivity type in third amorphous silicon layer 41a. Fourth amorphous silicon layer 42p is an example of a second silicon layer formed by a silicon-based thin film.

Second semiconductor layer 40 may be thick enough to sufficiently suppress recombination of optical carriers in second principal surface 22 of semiconductor substrate 20. The thickness of second semiconductor layer 40 is no less than 2 nm nor more than 75 nm, for example. More specifically, the thickness of third amorphous silicon layer 41a is, for example, no less than 1 nm nor more than 25 nm or preferably no less than 4 nm nor more than 15 nm. The thickness of fourth amorphous silicon layer 42p is, for example, no less than 1 nm nor more than 50 nm or preferably no less than 2 nm nor more than 10 nm.

The amorphous silicon layers (30a, 40a) may contain hydrogen (H) to enhance the effect of suppressing recombination of optical carriers. The amorphous silicon layers (30a, 40a) may contain oxygen (O), carbon (C), or germanium (Ge), in addition to hydrogen (H). A silicon oxide layer may be provided between semiconductor substrate 20 and each of the amorphous silicon layers (30a, 40a). In this case, the thickness of the silicon oxide layer is no less than 0.5 nm nor more than 5 nm, for example.

FIG. 3 illustrates the concentration profiles of phosphorus (P) and boron (B), in the thickness direction of semiconductor substrate 20, in each of first impurity region 23 of semiconductor substrate 20, third impurity region 25 of semiconductor substrate 20, third amorphous silicon layer 41a, and fourth amorphous silicon layer 42p. In FIG. 3, the solid line indicates the concentration profile of boron (B), and the dotted lines indicate the concentration profiles of phosphorus (P).

In the present embodiment, third impurity region 25 has a concentration gradient in which the impurity concentration of the first conductivity type decreases as the distance from second principal surface 22 increases. In addition, third amorphous silicon layer 41a has a concentration gradient in which the impurity concentration of the first conductivity type decreases as the distance from second principal surface 22 increases.

Third amorphous silicon layer 41a may experience an issue that the conductive property of third amorphous silicon layer 41a decreases because of an impurity, such as oxygen (O) or nitrogen (N), mixed in in the manufacturing process or the like. As a result, the resistive property of solar cell 10 may notably increase, and the power generation performance may decrease. At this point, adding a dopant of the second conductivity type to third amorphous silicon layer 41a allows the conductive property of third amorphous silicon layer 41a to improve. However, the function of separating the carriers while suppressing carrier recombination at the p-n junction formed between semiconductor substrate 20 of the first conductivity type and second semiconductor layer 40 of the second conductivity type decreases.

In contrast, adding a dopant of the first conductivity type appropriately to third amorphous silicon layer 41a makes it possible to improve the conductive property of third amorphous silicon layer 41a, and the function of separating the carriers while suppressing carrier recombination at the p-n junction formed between semiconductor substrate 20 of the first conductivity type and second semiconductor layer 40 of the second conductivity type can be retained high. This is possibly because, as compared to the case where a dopant of the second conductivity type is added to third amorphous silicon layer 41a, the region where the carriers are separated can be shifted from the junction interface between semiconductor substrate 20 and second semiconductor layer 40 where more defects are present in particular. Thus, the power generation performance of solar cell 10 can be improved.

An impurity that could be mixed in in the manufacturing process is present in a large amount particularly in the vicinity of second principal surface 22 in third amorphous silicon layer 41a, and it is considered that the conductive property may decrease particularly in the vicinity of second principal surface 22 in third amorphous silicon layer 41a. Therefore, when third amorphous silicon layer 41a has a concentration gradient in which the impurity concentration of the first conductivity type decreases as the distance from second principal surface 22 increases, the conductive property of third amorphous silicon layer 41a can be improved while the impurity concentration of the first conductivity type is being kept low, that is, while an occurrence of a defect caused by an impurity of the first conductivity type is being suppressed, and this is suitable for improving the power generation performance of solar cell 10.

Furthermore, in the present embodiment, when phosphorus (P) is used as an impurity of the first conductivity type and boron (B) is used as an impurity of the second conductivity type, phosphorus (P), as compared to boron (B), can improve the conductive property of amorphous silicon to a greater extend at a lower dopant concentration. This makes it possible to achieve amorphous silicon with higher conductive property and with less defect, and this is suitable for improving the power generation performance of solar cell 10.

As a result, a solar cell and a solar cell module with improved power generation performance can be provided.

As illustrated in FIG. 1, solar cell 10 includes first electrode and second electrode 60. First electrode 50 and second electrode 60 are spaced apart from each other. First electrode 50 is provided on first semiconductor layer 30 and electrically connected to first semiconductor layer 30. Meanwhile, second electrode 60 is provided on second semiconductor layer 40 and electrically connected to second semiconductor layer 40.

In the example described in the present embodiment, first electrode 50 is an n-side electrode, and second electrode 60 is a p-side electrode. The n-side electrode collects electrons generated in semiconductor substrate 20, and the p-side electrode collects holes generated in semiconductor substrate 20.

In the present embodiment, first electrode 50 has a structure in which first transparent conductive film 50t and first metal electrode 50m that is not transparent are laminated in this order on first semiconductor layer 30. First transparent conductive film 50t is provided on first semiconductor layer 30. First metal electrode 50m is provided on first transparent conductive film 50t. As illustrated in FIG. 2, first metal electrode 50m includes first busbar electrode 51m and a plurality of first finger electrodes 52m.

Meanwhile, second electrode 60 has a structure in which second transparent conductive film 60t and second metal electrode 60m that is not transparent are laminated in this order on second semiconductor layer 40. Second transparent conductive film 60t is provided on second semiconductor layer 40. Second metal electrode 60m is provided on second transparent conductive film 60t. Second metal electrode 60m includes second busbar electrode 61m (not illustrated) and a plurality of second finger electrodes 62m (not illustrated).

As illustrated in FIG. 1, first transparent conductive film 50t is provided in the entire region or in substantially the entire region on first semiconductor layer 30. Substantially the entire region on first semiconductor layer 30 is a region covering 90% or more of the surface on the light-receiving surface side of first semiconductor layer 30. First transparent conductive film 50t may be provided in the entire region on first semiconductor layer 30. First semiconductor layer 30 may be provided in the entire region on first principal surface 21 of semiconductor substrate 20, and first transparent conductive film 50t may be provided in the entire region on first semiconductor layer 30 on first principal surface 21 of semiconductor substrate 20.

Second transparent conductive film 60t is provided in the entire region or in substantially the entire region on second semiconductor layer 40. Substantially the entire region on second semiconductor layer 40 is a region covering 90% or more of the surface on the back surface side of second semiconductor layer 40. Second transparent conductive film 60t may be provided in substantially the entire region on second semiconductor layer 40. Second semiconductor layer 40 may be provided in the entire region on second principal surface 22 of semiconductor substrate 20, and second transparent conductive film 60t may be provided in substantially the entire region on second semiconductor layer 40 on second principal surface 22 of semiconductor substrate 20. In this case, substantially the entire region on second semiconductor layer 40 is a region covering preferably no less than 97% nor more than 99.5% of the surface on the back surface side of second semiconductor layer 40 excluding the outer edge portion thereof.

First transparent conductive film 50t and second transparent conductive film 60t include at least one metal oxide, such as indium oxide (In₂O₃), zinc oxide (ZnO), tin oxide (SnO₂), or titanium oxide (TiO₂), for example. An element such as tin (Sn), zinc (Zn), tungsten (W), antimony (Sb), titanium (Ti), cerium (Ce), or gallium (Ga) may be added to the above metal oxides. The thickness of each of the transparent conductive films (50t, 60t) is, for example, no less than 30 μm nor more than 200 μm or preferably no less than 40 μm nor more than 90 μm.

As illustrated in FIG. 2, first busbar electrode 51m is electrically connected to the plurality of first finger electrodes 52m and so disposed as to intersect with the plurality of first finger electrodes 52m. Meanwhile, second busbar electrode 61m is electrically connected to the plurality of second finger electrodes 62m and so disposed as to intersect with the plurality of second finger electrodes 62m.

First busbar electrode 51m and second busbar electrode 61m are each a plurality of linear electrodes, for example. The plurality of first finger electrodes 52m and the plurality of second finger electrodes 62m are each a plurality of thin linear electrodes disposed parallel to each other, for example. First metal electrode 50m and second metal electrode 60m may be constituted by the plurality of first finger electrodes 52m and the plurality of second finger electrodes 62m, respectively, without including first busbar electrode 51m and second busbar electrode 61m, respectively.

First busbar electrode 51m, second busbar electrode 61m, first finger electrodes 52m, and second finger electrodes 62m each have a thickness of no less than 5 μm nor more than 50 μm, for example. First busbar electrode 51m and second busbar electrode 61m each have a width of no less than 100 μm nor more than 2 mm, for example. First finger electrodes 52m and second finger electrodes 62m each have a width of no less than 20 μm nor more than 300 μm, for example. The plurality of first finger electrodes 52m and the plurality of second finger electrodes 62m each have a pitch of no less than 500 μm nor more than 3 mm, for example.

First metal electrode 50m and second metal electrode 60m are each formed of a metal, such as silver (Ag), copper (Cu), aluminum (Al), gold (Au), nickel (Ni), tin (Sn), or chromium (Cr), or formed of an alloy that includes at least one metal of the aforementioned metals. First metal electrode 50m and second metal electrode 60m may each be formed of a single layer or a plurality of layers.

When solar cell 10 is viewed in a plan view, the area of first metal electrode 50m may be smaller than the area of second metal electrode 60m. In addition, the number of first finger electrodes 52m may be smaller than the number of second finger electrodes 62m.

First electrode 50 and second electrode 60 do not need to include first transparent conductive film 50t and second transparent conductive film 60t, respectively. First metal electrode 50m and second metal electrode 60m may be directly connected to first semiconductor layer 30 and second semiconductor layer 40, respectively.

As described above, solar cell 10 according to an aspect of the present invention includes semiconductor substrate 20 having first principal surface 21 and second principal surface 22 and having the first conductivity type, third amorphous silicon layer 41a disposed on second principal surface 22, and fourth amorphous silicon layer 42p disposed on third amorphous silicon layer 41a and having the second conductivity type different from the first conductivity type. The impurity concentration of the first conductivity type in third amorphous silicon layer 41a is higher than the impurity concentration of the first conductivity type in semiconductor substrate 20 and lower than the impurity concentration of the second conductivity type in fourth amorphous silicon layer 42p.

Third amorphous silicon layer 41a has a concentration gradient in which the impurity concentration of the first conductivity type decreases as the distance from second principal surface 22 increases.

Solar cell 10 further includes a silicon oxide layer disposed between semiconductor substrate 20 and third amorphous silicon layer 41a.

Solar cell 10 further includes second electrode 60 disposed on fourth amorphous silicon layer 42p.

The first conductivity type is n-type, and the second conductivity type is p-type.

### [1.2 Method of Manufacturing Solar Cell]

A method of manufacturing solar cell 10 according to Embodiment 1 will be described.

In the present embodiment, first, a crystalline silicon substrate of the first conductivity type is prepared to serve as semiconductor substrate 20. The impurity concentration of the first conductivity type in semiconductor substrate 20 is, for example, no less than 5×10¹³ cm⁻³ nor more than 1×10¹⁷ cm⁻³ or preferably no less than 5×10¹⁴ cm⁻³ nor more than 2×10¹⁶ cm⁻³. The first principal surface and the second principal surface of the crystalline silicon substrate are a (100) plane.

Next, semiconductor substrate 20 is subjected to anisotropic etching. Thus, a concave and convex structure in which quadrangular pyramids having inclined surfaces in a (111) plane are arrayed two-dimensionally is formed in first principal surface 21 and second principal surface 22 of semiconductor substrate 20.

Specifically, first, semiconductor substrate 20 is immersed in an anisotropic etching solution. The anisotropic etching solution is an alkaline aqueous solution that includes at least one of sodium hydroxide (NaOH), potassium hydroxide (KOH), or tetramethylammonium hydroxide (TMAH), for example. Next, semiconductor substrate 20 is immersed in an isotropic etching solution. Thus, peaks and troughs of the textured structure are processed into a rounded shape. The isotropic etching solution is a mixed solution of hydrofluoric acid (HF) and nitric acid (HNO₃) or a mixed solution of hydrofluoric acid (HF), nitric acid (HNO₃), and acetic acid (CH₃COOH), for example. As the peaks and the troughs of the textured structure are processed into a rounded shape, any contact fracture of solar cell 10 can be suppressed.

Next, second impurity region 24 is formed in first principal surface 21 of semiconductor substrate 20, and third impurity region is formed in second principal surface 22. For example, phosphorus (P), arsenic (As), or antimony (Sb) can be used as an impurity of the first conductivity type in second impurity region 24 and third impurity region 25. Second impurity region 24 and third impurity region 25 can be formed, for example, through a thermal diffusion technique, a plasma doping technique, an epitaxial growth technique, an ion implantation technique, or the like.

When second impurity region 24 and third impurity region 25 are formed through a thermal diffusion technique, the use of POCl₃ gas in particular makes it possible to suitably add phosphorus (P), which is an impurity of the first conductivity type, while an occurrence of a defect in first principal surface 21 and second principal surface 22 of semiconductor substrate 20 is being suppressed. In place of POCl₃ gas, oxide films that contain phosphorus (P), which is an impurity of the first conductivity type, formed on first principal surface 21 and second principal surface 22 of semiconductor substrate 20 through a wet process can be used as a diffusion source of the phosphorus (P) dopant that is to serve as an impurity of the first conductivity type.

When second impurity region 24 and third impurity region 25 are formed through a plasma doping technique, a source material gas obtained by diluting phosphine (PH₃) with hydrogen (H₂) can be used, and the manufacturing cost can be reduced in a method of forming first semiconductor layer 30 and second semiconductor layer 40 through a chemical vapor deposition (CVD) technique, such as a plasma CVD technique.

When second impurity region 24 and third impurity region 25 are formed through an epitaxial growth technique, as compared to the case where a thermal diffusion technique is used, for example, the impurity concentration of the first conductivity type in second impurity region 24 and third impurity region 25 can be raised steeply at the interface between semiconductor substrate 20 and each of first semiconductor layer 30 and second semiconductor layer 40, and the impurity concentration of the first conductivity type in second impurity region 24 as a whole and third impurity region 25 as a whole can be made uniform with ease.

When second impurity region 24 and third impurity region 25 are formed through an ion implantation technique, high-temperature annealing may be used in combination to reduce any defect to be caused in ion implantation and to electrically activate the implanted ions.

When second impurity region 24 and third impurity region 25 are formed through a thermal diffusion technique or a plasma doping technique, a concentration gradient is formed in which the impurity concentration of the first conductivity type is at the highest at first principal surface 21 and second principal surface 22 of semiconductor substrate 20 and the impurity concentration of the first conductivity type gradually decreases as the distance from first principal surface 21 and the distance from second principal surface 22 increase. In other words, second impurity region 24 has a concentration gradient in which the impurity concentration of the first conductivity type decreases as the distance from first principal surface 21 increases. In addition, third impurity region 25 has a concentration gradient in which the impurity concentration of the first conductivity type decreases as the distance from second principal surface 22 increases.

Next, the amorphous silicon layers (30a, 40a) are formed on first principal surface 21 and second principal surface 22, respectively, of semiconductor substrate 20. The amorphous silicon layers (30a, 40a) can be formed through a CVD technique, such as a plasma CVD technique.

First amorphous silicon layer 31n and second amorphous silicon layer 32n can be formed with the use of a source material gas obtained by adding phosphine (PH₃) to silane (SiH₄) and diluting this with hydrogen (H₂). Third amorphous silicon layer 41a can be formed with the use of a source material gas obtained by adding phosphine (PH₃) to silane (SiH₄) and diluting this with hydrogen (H₂). Second amorphous silicon layer 32n and third amorphous silicon layer 41a can also be formed with phosphorus (P) mixed in from a manufacturing apparatus or the like. In other words, when second amorphous silicon layer 32n and third amorphous silicon layer 41a are formed through a CVD technique with the use of a source material gas obtained by diluting silane (SiH₄) with hydrogen (H₂), second amorphous silicon layer 32n and third amorphous silicon layer 41a can be doped suitably with phosphorus (P) as the phosphorus (P) adhering to a manufacturing apparatus or the like is mixed in to second amorphous silicon layer 32n and third amorphous silicon layer 41a. Fourth amorphous silicon layer 42p can be formed with the use of a source material gas obtained by adding diborane (B₂H₆) to silane (SiH₄) and diluting this with hydrogen (H₂).

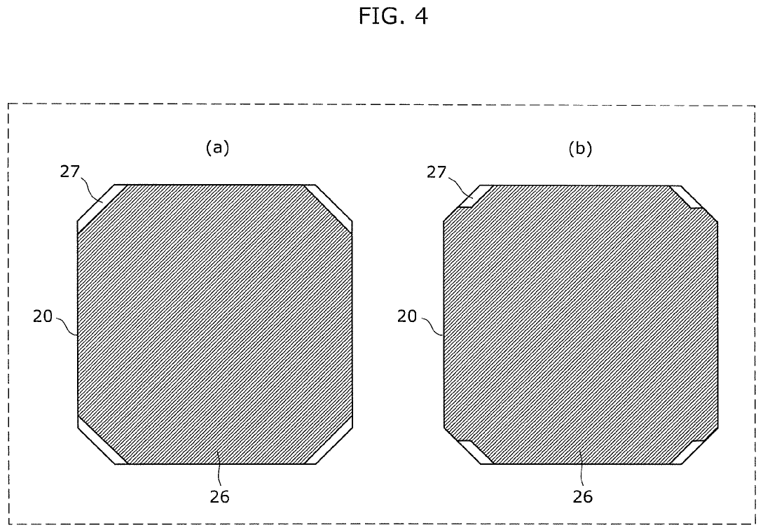

FIG. 4 is a front view in which an amorphous silicon layer is formed in substantially the entire region on semiconductor substrate 20. As illustrated in FIG. 4, the amorphous silicon layers (30a, 40a) can be formed not in the entire regions but in substantially the entire regions on first principal surface 21 and second principal surface 22, respectively, of semiconductor substrate 20. Through a CVD technique where a mask is used, thin-film deposited region 26 where an amorphous silicon layer is formed and thin-film non-deposited region 27 where no amorphous silicon layer is formed can be formed. As illustrated in (a) of FIG. 4, four thin-film non-deposited regions 27 can be formed only at the respective corners of semiconductor substrate 20. In FIG. 4, (b) illustrates an example of a variation from (a).

Next, the transparent conductive films (50t, 60t) are formed on first semiconductor layer 30 and second semiconductor layer 40, respectively. The transparent conductive films (50t, 60t) can be formed through a sputtering technique, a vapor deposition technique, or a CVD technique, for example.

Next, first metal electrode 50m and second metal electrode 60m are formed on the respective transparent conductive films (50t, 60t). First metal electrode 50m and second metal electrode 60m can be formed through a screen printing technique with the use of a conductive paste, such as a Ag paste, for example. After the conductive paste has been disposed through a screen printing technique, first metal electrode 50m and second metal electrode 60m can be formed by curing the conductive paste through drying or sintering. Alternatively, first metal electrode 50m and second metal electrode 60m can be formed through, for example but not limited to, an electrolytic plating technique or a vapor deposition technique.

### Embodiment 2

### [2.1 Configuration of Solar Cell According to Embodiment 2]

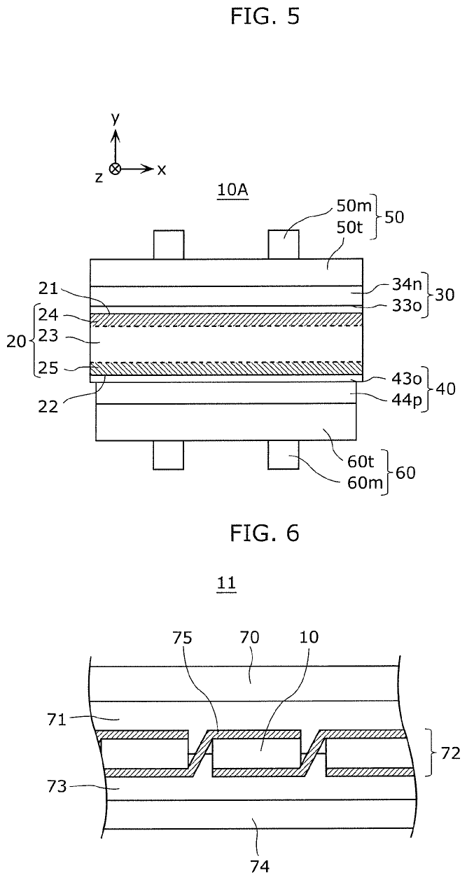

FIG. 5 is a sectional view illustrating a structure of solar cell 10A according to Embodiment 2. In the following, constituent elements similar to those in Embodiment 1 are given identical reference characters, and duplicate descriptions thereof will be omitted. As illustrated in FIG. 5, solar cell 10A according to the present embodiment differs from solar cell 10 according to Embodiment 1 in that first semiconductor layer 30 includes first silicon oxide layer 33o and second crystalline silicon layer 34n of the first conductivity type and in that second semiconductor layer 40 includes third silicon oxide layer 43o and fourth crystalline silicon layer 44p of the second conductivity type. Solar cell 10A includes first silicon oxide layer 33o and second crystalline silicon layer 34n in this order on first principal surface 21 of semiconductor substrate 20. In addition, solar cell 10A includes third silicon oxide layer 43o and fourth crystalline silicon layer 44p in this order on second principal surface 22 of semiconductor substrate 20.

First silicon oxide layer 33o and third silicon oxide layer 43o each have a film thickness of no less than 1 nm nor more than 5 nm, for example.

Second crystalline silicon layer 34n and fourth crystalline silicon layer 44p are each formed of monocrystalline silicon, polycrystalline silicon, or crystallite silicon. Second crystalline silicon layer 34n and fourth crystalline silicon layer 44p each have a film thickness of no less than 4 nm nor more than 400 nm, for example. The impurity concentration of the first conductivity type in second crystalline silicon layer 34n is, for example, no less than 1×10¹⁷ cm⁻³ nor more than 2×10²⁰ cm⁻³ or preferably no less than 5×10¹⁸ cm⁻³ nor more than 1×10²⁰ cm⁻³. The impurity concentration of the second conductivity type in fourth crystalline silicon layer 44p is, for example, no less than 1×10¹⁷ cm⁻³ nor more than 2×10²⁰ cm⁻³ or preferably no less than 5×10¹⁸ cm⁻³ nor more than 1×10²⁰ cm⁻³.

Third silicon oxide layer 43o contains an impurity of the first conductivity type. A dopant, such as phosphorus (P), arsenic (As), or antimony (Sb), is added to third silicon oxide layer 43o as an impurity of the first conductivity type, for example. The impurity concentration of the first conductivity type in third silicon oxide layer 43o is, for example, no less than 1×10¹⁶ cm⁻³ or preferably no less than 1×10¹⁷ cm⁻³ nor more than 1×10²⁰ cm⁻³. The impurity concentration of the first conductivity type in third silicon oxide layer 43o is higher than the impurity concentration of the first conductivity type in first impurity region 23 and third impurity region 25 of semiconductor substrate 20. The impurity concentration of the first conductivity type in third silicon oxide layer 43o may be lower than the impurity concentration of the first conductivity type in first silicon oxide layer 33o and second crystalline silicon layer 34n. Third silicon oxide layer 43o is an example of a first silicon layer formed by an amorphous silicon-based thin film.

The impurity concentration of the second conductivity type in fourth crystalline silicon layer 44p is higher than the impurity concentration of the first conductivity type in third silicon oxide layer 43o. Fourth crystalline silicon layer 44p is an example of a second silicon layer formed by a silicon-based thin film.

Adding a dopant of the first conductivity type appropriately to third silicon oxide layer 43o makes it possible to improve the conductive property of third silicon oxide layer 43o, and the function of separating the carriers while suppressing carrier recombination at the p-a junction formed between semiconductor substrate 20 of the first conductivity type and second semiconductor layer 40 of the second conductivity type can be retained high. Thus, the power generation performance of solar cell 10A can be improved.

### Embodiment 3

### [3.1 Configuration of Solar Cell Module According to Embodiment 3]

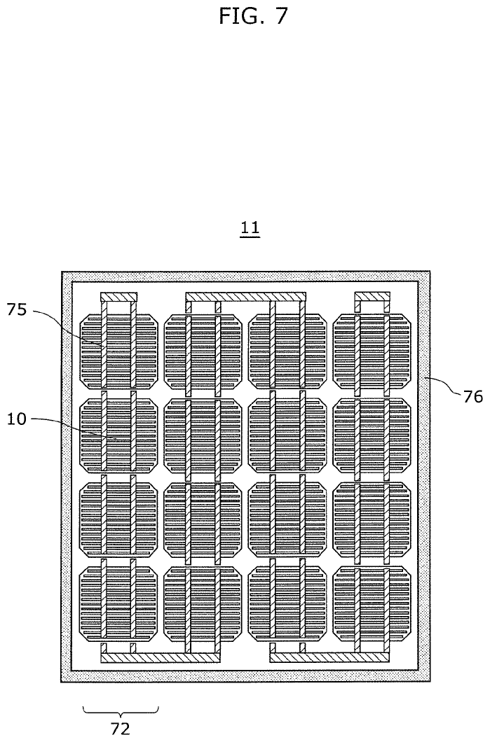

A schematic configuration of solar cell module 11 according to Embodiment 3 will be described with reference to FIGS. 6 and 7. FIG. 6 is a sectional view illustrating a structure of solar cell module 11 according to Embodiment 3. FIG. 7 is a plan view of a light-receiving surface side illustrating a structure of solar cell module 11 according to Embodiment 3. In the example described below, solar cell module 11 includes a plurality of solar cells 10. Alternatively, solar cell module 11 may include a plurality of solar cells 10A in place of solar cells 10.

As illustrated in FIGS. 6 and 7, solar cell module 11 has a layered structure in which light-receiving surface protecting material 70, light-receiving surface sealing material 71, solar cell string 72, back surface sealing material 73, and back surface protecting material 74 are laminated in this order. Solar cell string 72 is formed by electrically connecting a plurality of solar cells 10 in series with a plurality of wire members 75. Solar cell module 11 includes an enclosing frame 76.

Light-receiving surface protecting material 70 is glass, for example. Back surface protecting material 74 is an aluminum sheet or glass, for example. Light-receiving surface sealing material 71 and back surface sealing material 73 is ethylene vinyl acetate (EVA), for example. Wire members 75 are made of copper, for example. Frame 76 is made of aluminum, for example.

### Other Variations, Etc.

Thus far, the solar cell and the solar cell module according to some embodiments of the present invention have been described based on Embodiments 1 to 3, but the present invention is not limited to the foregoing embodiments. An embodiment obtained by making various modifications that a person skilled in the art can conceive of to the foregoing embodiments and an embodiment achieved by combining, as desired, the constituent elements and the functions in the embodiments within the scope that does not depart from the spirit of the present invention are also encompassed by the present invention.

In Embodiments 1 and 2, first principal surface 21 of semiconductor substrate 20 may be a back surface, and second principal surface 22 may be a light-receiving surface. In addition, the first conductivity type may be p-type, and the second conductivity type may be n-type.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell, comprising:
a semiconductor substrate having a first conductivity type;
a first silicon layer disposed on a principal surface of the semiconductor substrate, the first silicon layer including an amorphous silicon-based thin film; and
a second silicon layer disposed on the first silicon layer, the second silicon layer including a silicon-based thin film having a second conductivity type different from the first conductivity type, wherein
an impurity concentration of the first conductivity type in the first silicon layer is higher than an impurity concentration of the first conductivity type in the semiconductor substrate and lower than an impurity concentration of the second conductivity type in the second silicon layer.

2. The solar cell according to claim 1, wherein
the first silicon layer has a concentration gradient in which the impurity concentration of the first conductivity type decreases as a distance from the principal surface increases.

3. The solar cell according to claim 1, further comprising:
a silicon oxide layer disposed between the semiconductor substrate and the first silicon layer.

4. The solar cell according to claim 1, further comprising:
an electrode disposed on the second silicon layer.

5. The solar cell according to claim 1, wherein
the first conductivity type is n-type, and
the second conductivity type is p-type.

6. A solar cell module, comprising:
a solar cell string electrically connecting a plurality of solar cells in series with a plurality of wire members, wherein
the plurality of solar cells are each the solar cell according to claim 1.
